(19) United States
(12) Patent Application Publication
(10) Pub. No.: US 2023/0290553 A1
(43) Pub. Date: Sep. 14, 2023

(54) METHOD OF DESIGNING MAGNETISM IN COMPOSITIONALLY COMPLEX OXIDES

(71) Applicant: UT-Battelle, LLC, Oak Ridge, TN (US)

(72) Inventors: Thomas Z. Ward, Oak Ridge, TN (US); Matthew J. Brahlek, Oak Ridge, TN (US); Elbio R. Dagotto, Oak Ridge, TN (US); Alessandro R. Mazza, Oak Ridge, TN (US)

(21) Appl. No.: 18/118,804

(22) Filed: Mar. 8, 2023

Related U.S. Application Data
(60) Provisional application No. 63/318,441, filed on Mar. 10, 2022.

(51) Int. Cl. H01F 1/34; C30B 29/24

(52) U.S. Cl. CPC H01F 1/342; C30B 29/24

(57) ABSTRACT

A method of forming a single phase compositionally complex material including a plurality of transition metals is provided. The method includes creating a magnetic phase diagram to predict magnetic behavior, by calculating expected magnetic states and calculating the spin structure factor by Fourier transform; calculating the spin structure factor by Fourier transform; obtaining a transition temperature from the spin structure factor; selecting the plurality of transition metals and corresponding transition metal composition ratios for the material based on a desired magnetic behavior and the calculated spin structure factor; and forming the material that is a compositionally complex transition metal oxide comprising the plurality of transition metals at the selected composition ratios. The material may be a compositionally complex ABO₃ perovskite film in which A is La and B is the plurality of transition metals including Cr, Mn, Fe, Co, and Ni.

### CROSS-REFERENCE TO RELATED APPLICATIONS

This application claims the benefit of U.S. Provisional Application No. 63/318,441, filed Mar. 10, 2022, the disclosure of which is incorporated by reference in its entirety.

### STATEMENT REGARDING FEDERALLY SPONSORED RESEARCH AND DEVELOPMENT

This invention was made with government support under Contract No. DE-AC05-000R22725 awarded by the U.S. Department of Energy. The government has certain rights in the invention.

### FIELD OF THE INVENTION

The present invention relates to a method of forming compositionally complex oxide compositions as single crystal films and single phase bulk polycrystalline forms and other applications.

### BACKGROUND OF THE INVENTION

Magnetism is an easily observable quantum phenomenon and is a cornerstone of technologies ranging from magnetic memory, to spintronics, to future quantum sensing and computing applications. The type and strength of the magnetic state in crystalline materials is dictated by discrete values, such as the number of unpaired electrons and type of magnetic exchange interactions populating the crystal lattice. The development of predictive design strategies aimed at tailoring functional magnetic responses is then entirely reliant on the ability to not only computationally forecast what parameters must be present on a lattice to generate a required magnetic behavior, but these parameters must also be translated into real materials through synthesis. This is fundamentally challenging, since direct continuously tunable control over spin (S) and magnetic exchange (J) values is needed to access a precisely defined parameter space; however, these values must be experimentally created using the limited set of spin active elements. There are several indirect methods used to influence magnetic responses in strongly correlated materials, such as where heteroepitaxial effects and defect engineering are commonly used to manipulate spin-coupled charge and orbital parameters. Direct modification to the underlying S and J values using substitutional doping approaches are traditionally limited by thermodynamic processes during synthesis which can cause like elements to cluster or form secondary phases. Thus, while substitutional doping promises the most direct route to accessing the magnetic parameters used in computational approaches, enthalpic effects during synthesis can drive element segregation which limits mixing and reduces the number of desired composite microstates that exist in well-mixed regions. Recent developments in entropy-assisted synthesis provide a path to overcoming enthalpic effects and create well-mixed systems.

By greatly increasing the number of elements present in a material during synthesis, it is possible for entropic effects to dominate over enthalpy during crystal formation. The governing entropy ensures exceptional mixing, which maximizes the number of local microstates hosted on a lattice. Increasing local disorder in entropy stabilized materials is linked to significant functional improvements in thermal transport, ionic conductivity, and catalytic responses over less complex materials. Recent work has shown that this compositional disorder can be accommodated on ordered single crystalline lattices, which reduces the need to consider extrinsic parameters in computational models. With the development of single crystal synthesis, it is possible to more rationally design these systems to address previously inaccessible fundamental questions related to disorder while disentangling intrinsic from extrinsic effects that might be present in non-single crystal form factors.

Unlike high entropy alloys built from metal-metal bonded elements, high entropy oxides give access to functionalities in covalent and ionic bonded materials. While the metal-bonded high entropy alloys are limited in their range of crystal structures, stability, and accessible magnetic interaction pallet, the addition of an anion sublattice enables a broad range of stable crystal structures and greater access to functional diversity. Still, considering the sensitivity of spin behavior to bond angles and cation orbital filling in many oxide systems, it is surprising that high entropy oxides hosting high levels of compositional disorder have been reported to support signatures of long range magnetic ordering in both relatively simple rock salt lattices and more complicated spinel and perovskite structures. In explaining this emergent long-range magnetic order in the rock salt (Mg_{0.2}Co_{0.2}Ni_{0.2}Cu_{0.2}Zn_{0.2})O, the antiferromagnetic order is found to be a direct result of each of the species having antiferromagnetic exchange interactions. Of broader interests, the local exchange and spin disorder hosted in these compositionally complex systems may provide critical insights on the role of disorder in degeneracy-driven magnetic dynamics and phase competition, where mixed phase could lead to the emergence of interesting phenomena like exchange bias. In all cases, the mechanism of ordering revolves around the type and strength of exchange couplings populating the lattices as a function of the elemental compositions. This is fundamentally different from the itinerant RKKY or dilute type magnetism observed in metal-metal bonded systems. The addition of the anion sublattice in the high entropy oxides promises a greater diversity of magnetic interactions enabled by localized rather than delocalized electron coordination.

The presence of correlated states in compositionally complex oxides including high entropy transition metal oxides and the resulting increase in complex microstates comes at the cost of greatly decreasing the feasibility of producing accurate descriptions of these systems using computationally intensive first principles approaches. Even with the large body of work in literature on low complexity transition metal oxide materials, functional theoretical modelling of the high entropy oxides has been extremely limited. Electron correlation and many-body effects combined with the range of possible microstates in a compositionally complex system have made precise quantitative calculations impractical. For example, a B-site in a simple ternary ABO3 perovskite is surrounded by like elements on the B-O-B sublattice so has only one possible nearest neighbor and next nearest neighbor arrangement. In a high entropy perovskite oxide system with five different cations residing on the B-site sublattice, there are more than 200 possible nearest neighbor combinations for each of the five different elements. Importantly, the microstates with the highest probability of being populated are those in which all five elements are present in the next nearest neighbor positions. That is to say, the importance of low complexity microstates whose values can be directly harvested from literature is reduced as the number of different elements in the magnetic lattice increases. Thus, correlated high complexity oxides possess local environments that are fundamentally different than the less complex parent compounds which can be expected to lead to functionalities not present in low complexity systems. To gain insights into the high complexity systems, there is an outstanding need to experimentally control for cation variances and identify a means to model emergent responses in a computationally accessible manner.

### SUMMARY OF THE INVENTION

With the development of single crystal synthesis, it is possible to more rationally design compositionally complex systems to address previously inaccessible fundamental questions related to disorder while disentangling intrinsic from extrinsic effects that are often present in non-single crystal form factors. Compositionally complex materials (CCMs) include as a partial subset some high entropy oxides (HEOs) which further include entropy stabilized oxides (ESOs) as a sub-subset. The effects of known element-specific parameters and inter-atomic couplings are microscopically mapped herein to materials of extraordinary compositional complexity to predict macroscopic collective behavior, and critically, these compositionally complex but structurally uniform crystals can be synthesized in the real world. Compositionally disordered but positionally ordered lattices produced using entropy-assisted synthesis thereby allows for the creation of materials with very specific macroscopic magnetic responses.

More particularly, a method of forming a single phase compositionally complex material including a plurality of transition metals includes creating a magnetic phase diagram to predict magnetic behavior, by calculating expected local magnetic states leading to macroscopic behavior using the formula:

$$H = {\sum }_{< ij >} {J}_{ij} {S}_{i} \cdot {S}_{j}$$

wherein Sᵢ are spin values depending on which transition metal is placed at site i, Sⱼ are spin values depending on which transition metal is placed at site j, <ij> refers to next nearest-neighbor sites, and Jᵢⱼ are magnetic exchange values, and calculating the spin structure factor S(k) by Fourier transform, using the formula:

$$S ( k ) = \frac{1}{N} {\sum }_{i , j} 〈 {S}_{i} \cdot {S}_{j} 〉 {e}^{ik \cdot 〈 {r}_{i} - {r}_{j} 〉}$$

wherein rᵢ is the vector position of site i, rⱼ is the vector position of site j, k is the wavevector that is set to (0,0,0) and (½,½,½), and <Sᵢ·Sⱼ> are the standard spin-spin correlations in real space at all distances. The method further includes obtaining a transition temperature from the spin structure factor. The method further includes selecting the plurality of transition metals and corresponding transition metal composition ratios for the single phase compositionally complex material based on a desired magnetic behavior and the calculated spin structure factor S(k). The method also includes forming the single phase compositionally complex material, wherein the single phase compositionally complex material is a compositionally complex transition metal oxide comprising the plurality of transition metals at the selected composition ratios.

In specific embodiments, the spin values S are: (i) S=5/2 when the transition metal is Fe; (ii) S=2 when the transition metal is Co; (iii) S=3/2 when the transition metal is Mn; (iv) S=3/2 when the transition metal is Cr; and (v) S=1 when the transition metal is Ni.

In specific embodiments, the magnetic exchange values J are obtained from Table 1 below.

In specific embodiments, the step of creating a magnetic phase diagram includes varying a compositional amount of one of the transition metals and repeating the calculation of the expected local magnetic states and spin structure factor S(k) for each compositional amount.

In specific embodiments, the plurality of transition metals includes more than three transition metals.

In specific embodiments, the compositionally complex transition metal oxide is La(CrₐMn_{b}Fe_{c}Co_{d}Niₑ)O₃ in which a+b+c+d+e=1 and each of a, b, c, d, and e is greater than 0 and less than 1.

In particular embodiments, the method further includes the step of varying one or more of a, b, c, d, and e in the range of 0.1 to 0.9.

In specific embodiments, the compositionally complex transition metal oxide is La(Cr_{(1-n)/4}MnₙFe_{(1-n)/4}Co_{(1-n)/4}Ni_{(1-n)/4})O₃, 0>n>1 and n is selected based on the desired magnetic behavior and transition temperature.

In specific embodiments, the compositionally complex transition metal oxide is La(Cr_{(1-n)/4}Mn_{(1-n)/4}FeₙCo_{(1-n)/4}Ni_{(1-n)/4})O₃, 0>n>1 and n is selected based on the desired magnetic behavior and transition temperature.

In specific embodiments, the compositionally complex transition metal oxide is La(CrₙMn_{(1-n)/4}Fe_{(1-n)/4}Co_{(1-n)/4}Ni_{(1-n)/4})O₃, 0>n>1 and n is selected based on the desired magnetic behavior and transition temperature.

In specific embodiments, the compositionally complex transition metal oxide is La(Cr_{(1-n)/4}Mn_{(1-n)/4}Fe_{(1-n)/4}CoₙNi_{(1-n)/4})O₃, 0>n>1 and n is selected based on the desired magnetic behavior and transition temperature.

In specific embodiments, the compositionally complex transition metal oxide is La(Cr_{(1-n)/4}Mn_{(1-n)/4}Fe_{(1-n)/4}Co_{(1-n)/4}Niₙ)O₃, 0>n>1 and n is selected based on the desired magnetic behavior and transition temperature.

In specific embodiments, the desired magnetic behavior is one of antiferromagnetism, paramagnetism, ferromagnetism, and magnetic frustration of co-existing states.

A single crystal film formed by the method is also provided. In specific embodiments, the single crystal film is a compositionally complex ABO₃ perovskite film. In particular embodiments, A is La and B is the plurality of transition metals including Cr, Mn, Fe, Co, and Ni. In specific embodiments, the single crystal film exhibits exchange bias.

A compositionally complex transition metal oxide is also provided having the formula La(CrₐMn_{b}Fe_{c}Co_{d}Niₑ)O₃ wherein a+b+c+d+e=1 and each of a, b, c, d, and e is greater than 0 and less than 1. In certain embodiments, the compositionally complex transition metal oxide has the formula La(Cr_{(1-n)/4}MnₙFe_{(1-n)/4}Co_{(1-n)/4}Ni_{(1-n)/4})O₃ wherein 0>n>1, i.e. in the preceding formula a=(1−n)/4, b=n, c=(1−n)/4, d=(1−n)/4, e=(1−n)/4. In other embodiments, any one of a, b, c, d, and e is equal to n, and the others of a, b, c, d, and e are each equal to (1−n)/4.

These and other features of the invention will be more fully understood and appreciated by reference to the description of the embodiments and the drawings.

### BRIEF DESCRIPTION OF THE DRAWINGS

FIG. 1 is a flowchart of a method of forming a monolithic single crystal film of a compositionally complex oxide in accordance with embodiments of the disclosure;

FIG. 2 is diagram of magnetic ordering type and magnetic exchange values (J) for various oxygen mediated metal-to-metal nearest neighbor interactions;

FIG. 3 is a graph of the calculated spin structure factor S(k_{AFM}) at wavevector k_{AFM} equal to (π, π, π) for antiferromagnetic ordering versus temperature T/J where J is 180K for L5BO in comparison to two non-complex metal oxides;

FIG. 4 is a graph of the spin structure factor S(k_{AFM, FM}) versus temperature T/J at various percentages of Mn in L5BO while the other four elements were equally distributed in percent;

FIG. 5 is a magnetic phase diagram as a function of Mn content derived in accordance with certain embodiments of the method;

FIG. 6 is a graph of field cooled (FC) and zero field cooled (ZFC) temperature dependent magnetization taken under a 1 kOe field for synthesized 20% Mn, 40% Mn, and 60% Mn L5BO single crystal films;

FIGS. 7a-c are graphs of magnetization loops taken at 2 K after field cooling under ±7 T for synthesized 20% Mn, 40% Mn, and 60% Mn L5BO single crystal films; and

FIGS. 8a-c are diagrams of (J Sᵢ·Sⱼ) cross-sections derived in accordance with certain embodiments of the method for L5BO with 20% Mn, 40% Mn, and 60% Mn.

### DETAILED DESCRIPTION OF THE CURRENT EMBODIMENTS

A range of single crystal entropy-stabilized ABO₃ perovskite films were synthesized to probe the role of site-to-site spin and exchange interaction variances in stabilizing emergent magnetic behaviors. The complexity of this system provides tunability and functionality not present in any of the ternary or half-doped quaternary parents or as a simple sum of their properties. Neutron diffraction and magnetometry show that the compositionally disordered systems can paradoxically host long-range magnetic order, while manipulation of the S and J parameters through cation ratio permits continuous control of magnetic phase from antiferromagnetism (AFM), to degenerate, to ferromagnetism (FM). Tuning of the coexisting magnetic phase composition also allows for the design of exchange bias behaviors in monolithic single crystal films, which previously were only observed in AFM-FM bilayer heterojunctions or 2D layered bulk systems. In spite of the extraordinary levels of microstate complexity, a classical Heisenberg model populated with composite parameter states as described herein produces an astonishingly accurate magnetic phase diagram that provides insights into the mechanisms driving the emergence of macroscopic magnetic states. This provides a practical means of predicting how to manipulate the parameter ratios to stabilize desired states for functional design of materials with high compositional complexity.

La(Cr_{0.2}Mn_{0.2}Fe_{0.2}Co_{0.2}Ni_{0.2})O₃ (L5BO) is a high entropy oxide system that herein is used to model the role of local magnetic disorder on the emergence of macroscopic magnetic behaviors. Structurally, this ABO₃ perovskite possesses full mixing of the B-site cations while maintaining long-range single crystal lattice uniformity. There are many theoretical and experimental studies on the parent compounds, LaCrO₃, LaMnO₃, LaFeO₃, LaCoO₃, and LaNiO₃ and a range of interfacial and co-doping studies that provide insights into expected spin, charge, and oxygen-mediated coupling types between different 3d transition metal cations across a range of structural distortions and dimensionalities. These studies provide a starting point to understanding nearest neighbor interactions and point to there being a wide range of different spin and exchange interactions coexisting in the high entropy systems. These previous works, however, provide no direct insights into how magnetism might evolve when combined in a randomly populated system where next nearest neighbors can vary widely.

Neutron diffraction on the L5BO system shows that its complex mix of local microstates hosts robust long-range macroscopic AFM ordering in both the bulk powder ceramic and single crystal thin film forms. It is noted that the cubic Miller indices of the film, where the (0 0 1) peak refers to the structural and temperature-independent feature in the powder diffraction, and the (π π π) peak (i.e., the (½ ½ ½) peak) is an AFM Bragg peak, only occur below the Neel temperature (T_{N}). The temperature dependence of the (½ ½ ½) peak of the L5BO in polycrystalline form provides an order parameter that shows an onset of AFM occurring between the measurements taken at 300 K and 150 K, which is consistent with previous studies of L5BO powder produced by spray pyrolysis. Since single crystals may help preclude possible extrinsic contributions related to complexity of grain size, surface effects, and inhomogeneous mixing of constituents, neutron diffraction is also performed on single crystal films grown on near lattice matched (LaAlO₃)_{0.3}(Sr₂TₐAlO₆)_{0.7} (LSAT) substrates to allow the film to maintain a nearly cubic structure. The temperature-dependent evolution of the (½ ½ ½) peak for a 90 nm film demonstrates a clear G-type AFM transition in the L5BO film. These single crystal films show no sign of relaxation and have rocking curve widths <0.08°. While the exact onset temperature is hidden at higher temperatures by the substrate background signal, the onset trend agrees with irreversibility in temperature-dependent magnetization in the field cooled vs zero field cooled SQUID magnetometry results, implying that the Neel temperature occurs near 180 K.

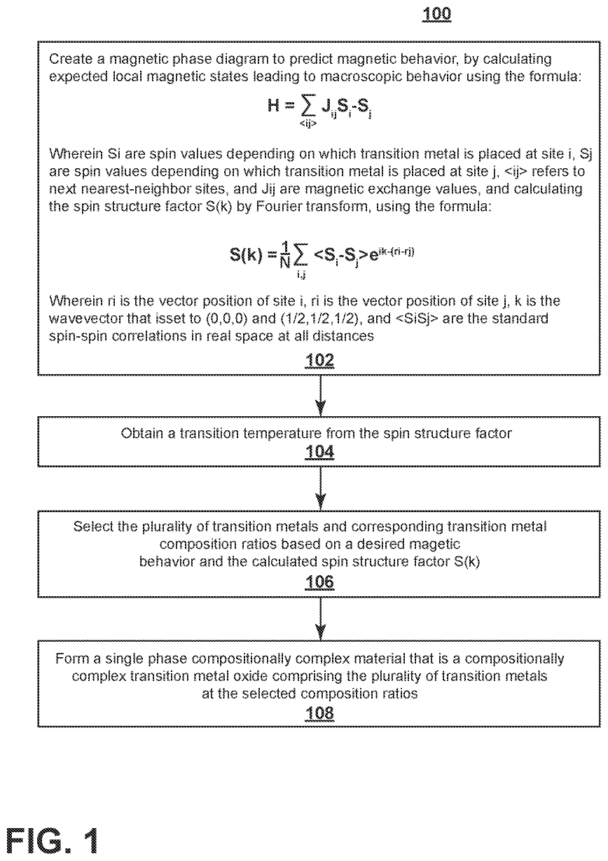

The observed long-range magnetic order is remarkable considering the local spin and exchange disorder hosted within the lattice. In understanding how order emerges from disorder, a classical model for a square lattice populated by a range of possible exchange interactions distributed across the lattice can provide initial insights. In the present method as shown in FIG. 1, to predict the magnetic behavior of L5BO, at step 102 of the method 100 a Monte Carlo study is performed on a cubic lattice by calculating the expected local magnetic states leading to macroscopic behavior using the classical Heisenberg model defined as:

H=Σ_{<ij>}JᵢⱼSᵢ·Sⱼ (Equation 1)

in which Sᵢ and Sⱼ are classical spins of different magnitudes depending on which transition metal element is placed at site i or j in the cubic lattice. The symbol <ij> in Equation 1 refers to nearest-neighbor (NN) sites. For the location of the spins, a random distribution based on a probability is used such that each element covers 20% of the finite clusters employed for the simulation.

An annealing process from high temperature (i.e., slow cooling) is employed to avoid being trapped into metastable states. Simulations of different cluster size (10×10×10 and 12×12×12) are repeated and the results for critical temperatures do not change appreciably ensuring the results are not impacted by sample size. Moreover, the Monte Carlo results shown herein by way of example correspond to averages over five independent random distributions of spins, but self-averaging renders the five results nearly identical within the accuracy needed. This comparison provides an interesting point, by suggesting it is this average which dictates the predominant order type in the film. After equilibrium, Monte Carlo is used to measure the standard spin-spin correlations <Si·Sj> in real space at all distances and from them calculate the spin structure factor S(k) by Fourier transform using the following formula:

$$S ( k ) = \frac{1}{N} {\sum }_{i , j} 〈 {S}_{i} \cdot {S}_{j} 〉 {e}^{ik \cdot 〈 {r}_{i} - {r}_{j} 〉} \qquad ( Equation 2 )$$

in which rᵢ is the vector position in the cubic lattice of site i and rⱼ is the vector position of site j. Among allowed momenta, the one that maximizes S(k) is chosen. In all simulations of the equiatomic B-site perovskite using the couplings and spins discussed below, the dominant peak in S(k) is always found to be located at (π, π, π), i.e., in the AFM position.

A calculation of the magnetic order parameter can be found by considering the highest probability microstates in a random distribution on the perovskite lattice. The fact that the cations in the L5BO system randomly populate a lattice that, while uniform, is neither identical to a specific parent material nor an average of all parents makes direct gathering of S and J values from literature difficult. There is little known about the way many of these cations will couple for a single isolated bond while neglecting the other five nearest neighbors, which could influence charge and orbital state. It is important to assign values that would have the highest probability of being most valid when randomly distributed throughout a chaotic compositional landscape hosted on a well-ordered lattice. In a randomly mixed system, the central element has the highest probability of being coordinated to several different transition metals. There are uncertainties in selecting spin and exchange values in a random B-site occupancy, which results from the influence of nearest neighbors that are not present if these values were to be taken from previous reports on low complexity ternary or quaternary parent systems. For example, in a pure ternary parent material, such as LaMnO₃ a central element is surrounded by 6 coordinated elements which are the same. Thus, there is only one possible state for that central element, such as Mn[Mn,Mn,Mn,Mn,Mn,Mn], where elements enclosed in the bracket are the six coordinated elements. However, assume a different system where a Mn is surrounded by five Mn and one Ni. Mn will charge balance to the Ni and result in Mn³⁺+Ni³⁺→Mn⁴⁺+Ni²⁺. This changes the spin state of the Mn and makes that Mn's bonding to the other five bonded Mn different than the idealized parent. Any changes to the local coordination system can very quickly change values that might be reported from the ideal ternary systems. Assigning exact interactions for all Mn—Mn bonds when scenarios such as this are possible requires making a best approximation using all available information from literature and match that to a best fit of the most widely probable populating interaction value. Considering that in the L5BO system random probability results in an approximately 75% chance that at least one of the six nearest neighbor transition metals surrounding the central Mn is a Ni. One could calculate the full Hamiltonian for the central Mn cation in a configuration where it was coordinated to five Mn and one Ni (while also ignoring NNN, anisotropy from distortion, etc. to keep the single state calculation as simple as possible). However, if one were to take this approach to modelling the whole L5BO system, it would also be necessary to calculate all 210 cation combinations that are possible around the Mn in the 6-fold coordination. This is computationally impossible. The entropy-stabilized system requires a streamlined method that captures the complexity while simplifying the minutia. Not only does the exact state Mn[Mn,Mn,Mn,Mn,Mn,Mn] have little bearing on the whole system as complexity increases, but the realistic addition of next, next nearest neighbors and a crystal structure different than the bulk ternary would have a strong influence on the validity of the Mn[Mn,Mn,Mn,Mn,Mn,Mn] in the mixed systems. That is to say, a central Mn interaction with one of its coordinated Mn nearest neighbors in the state Mn[Mn,Mn,Mn,Mn,Mn,Mn] would be different than a central Mn interaction with one of its coordinated Mn nearest neighbors in the state Mn[Mn,Mn,Ni,Mn,Mn,Mn]. Following are details as to how S and J parameters were selected for the Heisenberg model presented above.

The superexchange values J(X,Y) must be set for each of the 15 independent combinations X—O—Y. Here X and Y are any of the five elements Cr, Mn, Fe, Co, or Ni, and O represents the oxygen the mediates the bond between nearest neighbor X and Y elements. The classical Monte Carlo simulation of the 3D Heisenberg model defined above has an antiferromagnetic Néel critical temperature T_{N}=1.44 J when the spins at every site have magnitude S=1. Note also that in a bipartite lattice, as the cubic lattice used here, the sign of the spins at the “even” sites can be changed, and the model transforms into the ferromagnetic classical Heisenberg model with the same Curie temperature T_{C}=1.44 J. Thus, at the classical level the 1.44 is common to FM and AFM states.

The spin values are relatively easy to predict in magnitude once charge rebalancing is considered, but the values Jᵢⱼ are more difficult because there are 15 possible combinations X—O—Y (with X,Y=Cr, Mn, Fe, Co, Ni). For the 5 X—O—X cases, this task is simplified, because the critical temperatures of the LaXO₃ materials can be directly related to their superexchange J, positive or negative depending on whether the order is AFM or FM. For the other 10 X—O—Y (X≠Y) cases, finding Jᵢⱼ is more challenging and critical temperatures for 50% mixes LaX_{0.5}Y_{0.5}O₃, superlattices LaXO₃—LaYO₃, or in some cases interpolations between existing data were used. The results of this effort are as follows.

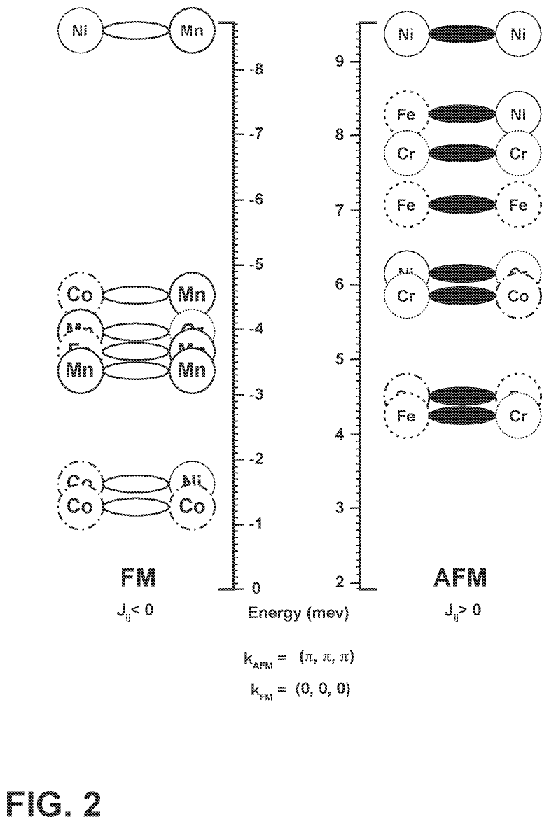

There are 8 AFM Jᵢⱼ>0 and 7 FM Jᵢⱼ<0 as shown in FIG. 2, suggesting a fine balance between the two tendencies. However, the actual magnitudes of the AFM set Jij>0 are considerably stronger than those with FM character. Moreover, the largest spin S=5/2 for Fe³⁺ plays an important role for the AFM dominance. Charge redistribution and disproportionation can occur when linking certain transition metals through an oxygen bond which changes accessible charge state and resulting spin state; the most well-known being the strong preference of Mn³⁺+Ni³⁺→Mn⁴⁺+Ni²⁺ and the slightly less favorable Mn³⁺+Co³⁺→Mn⁴⁺+Co²⁺. This charge rebalancing is a known process in L5BO crystals as a driving factor in generating its unexpected crystalline uniformity and must be considered when selecting parameter values that have the highest probability of being in the majority. With these considerations, the magnitudes of the spin of each transition metal ion are S=5/2 for Fe, S=2 for Co, S=3/2 for Mn and Cr, and S=1 for Ni. However, it should be understood that these S values are determined for a 20% Mn B-site composition. The S values may vary depending on the ratio of compositions of the transition metals at the B sites. For example, in the 20% Mn composition, the charge states of Mn and Ni are Mn⁴⁺ and Ni²⁺ instead of Mn³⁺ and Ni³⁺ because Ni has greater affinity for electrons than Mn when they are nearest neighbors and Ni therefore pulls charge from the Mn. When the percentage of Mn is increased significantly, there is less Ni present to pull charge from Mn so the charge state of Mn decreases to 3+.

As for J, the simplest five cases are those of the “diagonal” form X—O—X.
(i) For X=Fe, LaFeO₃ is known to be a G-type AFM with T_{N}=740 K. By a simple rescaling of parameters, namely introducing the S=5/2 of Fe, leads to the equality 740 K=1.44 J(Fe,Fe) (5/2)(5/2), thereby obtaining J(Fe,Fe)=+82 K which corresponds to an exchange value J of 7.1 millielectron-volt (mev).
(ii) For X=Cr, LaCrO₃ is also known to be a G-type AFM but with T_{N}=290 K. By the same procedure as in (i) but using S=3/2, J(Cr,Cr)=+90 K, similar to J(Fe,Fe), which corresponds to an exchange value J of 7.8 mev.
(iii) For X=Mn, LaMnO₃ is known to be an A-type AFM with T_{N}=140 K. This magnetic arrangement has wavevector (0,0,π), i.e. FM in plane and AFM between planes. However, under strain the entire system becomes FM showing that the FM and A-type AFM states are close in energy. Employing a direction-dependent J(Mn,Mn) would add too much complexity to the theory description, thus for simplicity a FM superexchange is used (for strained films) in all three directions. Employing the same strategy as before in (i) leads to J(Mn,Mn)=−40 K (corresponding to −3.4 mev) using S=3/2. S=3/2, which is also practically reasonable as charge redistribution is a well-known occurrence when Mn has a nearest neighbor of other transition metals such as Ni or Co, which is required in the well-mixed L5BO crystals. Note that in Mn-oxide compounds double-exchange physics likely dominates, with coexisting itinerant and mobile holes, thus a negative FM superexchange is merely a simplified effective description of a far more complex mechanism for ferromagnetism.
(iv) For X=Co, LaCoO₃ is considered to be non-magnetic due a close energy competition between the high S=2 and low S=0 spin states, caused by competing Hund interaction and crystal field split energies between the x²-y2 and 3z²-r² orbitals. However, in thin-films LaCoO₃ becomes FM with T_{C}=90 K. As in (i), this leads to J(Co,Co)=−16 K (corresponding to −1.4 mev) for the case S=2. This small value of J(Co,Co) is probably a consequence of the still present competition S=0 vs. 2 in the thin films. If the average Co spin were e.g. S=1, then J(Co,Co) would increase by a factor 4 to values similar to those of previous cases. Note that S=0 is used for Co as well, and thus J(Co,Y) was effectively 0. In this case, the AFM critical temperature of cobalt S=0 was found to be smaller than S=2 in L5BO.
(v) For X=Ni, LaNiO₃ presents a similar difficulty as LaCoO₃. In bulk form LaNiO₃ is non-magnetic in the long-range sense. However, Ni ion likely has a nonzero spin. Moreover, in superlattices a noncollinear canting state with T_{N}=157 K was found. Describing non-collinear spin arrangements would require antisymmetric spin-spin terms or high frustration, complicating the description. Thus, for simplicity the canonical S=1 is assumed for Ni, and an AFM NN superexchange (no antisymmetric extra term). S=1 is also practically reasonable as charge disproportination is a well-known occurrence when Ni has a nearest neighbor of other transition metals such as Mn, which is required in the well mixed L5BO crystals. By the procedure in (i) this results in J(Ni,Ni)=+109 K (corresponding to 9.4 mev), comparable to Fe and Cr.

The remaining 10 non-diagonal J(X,Y) (with X≠Y) are more complicated to define.
(vi) For X=Fe and Y=Mn, superlattices of LaFeO₃ and LaMnO₃ indicate ferromagnetic order at T_{C}=230 K. Following the procedure in (i) leads to J(Fe—Mn)=−43 K (corresponding to −3.7 mev). Note that the alloy LaFe_{0.5}Mn_{0.5}O₃ is also ferromagnetic albeit with T_{C}=380 K, providing reassurance that J(Fe,Mn) is FM.
(vii) For X=Fe and Y=Cr, the alloy LaFe_{0.5}Cr_{0.5}O₃ was reported to be AFM with T_{N}=265 K. This leads to J(Fe,Cr)=+49 K (corresponding to 4.2 mev).
(viii) For X=Mn and Y=Ni, two different FM transitions have been observed in alloy LaMn_{0.5}Ni_{0.5}O₃ at T_{C}=150 K and T_{C}=280 K. There is a well-known charge disproportionation that occurs in this combination. For simplicity, the average was considered, leading to J(Mn,Ni)=−100 K (corresponding to −8.6 mev).
(ix) For X=Mn and Y=Co, the alloy LaMn_{0.5}Co_{0.5}O₃ has a FM transition at T_{C}=230 K leading to J(Mn,Co)=−53 K (corresponding to −4.6 mev).
(x) For X=Co and Y=Ni, the alloy LaCo_{0.5}Ni_{0.5}O₃ has a FM transition at T_{C}=53 K leading to J(Co,Ni)=−18 K (corresponding to −1.6 mev).
(xi) For X=Fe and Y=Co, studies of LaFe_{0.5}Co_{0.5}O₃ has a canted AFM state with T_{N}=370 K, leading to J(Fe,Co)=+51 K (corresponding to 4.4 mev).
(xii) For X=Co and Y=Cr, studies of LaCo_{0.5}Cr_{0.5}O₃ has a canted AFM with T_{N}=295 K, leading to J(Co,Cr)=+68 K (corresponding to 5.9 mev).
(xiii) For X=Fe and Y=Ni, studies suggest low temperature glassy behavior for the 50-50 alloy which does not allow selection of a discrete value for purposes herein. Thus, from the above calculated J(Fe,Fe) and J(Ni,Ni), both AFM and similar in value, an average can be obtained which leads to J(Fe,Ni)=+96 K (corresponding to 8.3 mev).
(xiv) For X=Mn and Y=Cr, no useful information exists for the 50-50 alloy. However, there is a clear smooth behavior for the values of J(Mn,Y) deduced thus far (all FM): J(Mn,Mn)=−40.1 K, J(Mn,Co)=−53.2K, J(Mn,Fe)=−42.6K, and J(Mn,Ni)=−69.4K. Since Cr is closer to (Mn,Fe,Co) than Ni in the periodic table, the first three are used for an average which leads to J(Mn,Cr)=−45 K (corresponding to −3.9 mev).
(xv) For X=Cr and Y=Ni, no useful information exists for the 50-50 alloy. The above estimated FM value for J(Mn,Cr) is believed to be negative primarily because of the influence of Mn, that has all the links FM. Thus, a crude average of the other existing AFM superexchanges J(Cr,Y) is used, with Y=Cr, Fe, and Co, leading to J(Cr,Ni)=+70 K (corresponding to 6.0 mev). The AFM character assumption is reasonable because both J(Cr,Cr) and J(Ni,Ni) are both AFM.

The estimations of J(X,Y) provided above seem somewhat chaotic. However, upon further scrutiny, patterns emerge. The signs are approximately evenly divided with eight values AFM and seven FM. Moreover, the largest AFM J(Ni,Ni)=+109K and the largest FM J(Mn,Ni)=−100K are quite similar in magnitude, and very close to the J(Fe,Fe)=+82K used for the critical temperature estimations. Further, there is a clear trend in exchange type preferences for two of the five elements. The overall dominance of AFM can be linked to Fe which has antiferromagnetic tendencies in four of its five oxygen-mediated bonds i.e., in Fe—O—Fe, Fe—O—Cr, Fe—O—Co, and Fe—O—Ni. On the other hand, Mn strongly favors FM coupling. The magnetic exchange values obtained herein are also shown in Table 1 below.

TABLE 1
Magnetic exchange values for oxygen
mediated couplings X-X or X-Y

| Coupling (oxygen-mediated | Exchange |
|---|---|
| occupancy at lattice sites ij) | Value J (mev) |
| Ni—Mn | −8.6 |
| Co—Mn | −4.6 |
| Mn—Cr | −3.9 |
| Fe—Mn | −3.7 |
| Mn—Mn | −3.4 |
| Co—Ni | −1.6 |
| Co—Co | −1.4 |
| Fe—Cr | 4.2 |
| Co—Fe | 4.4 |
| Cr—Co | 5.9 |
| Ni—Cr | 6.0 |
| Fe—Fe | 7.1 |
| Cr—Cr | 7.8 |
| Fe—Ni | 8.3 |
| Ni—Ni | 9.4 |

Furthermore, defining an overall scale “J” crudely in the range from 70 to 100K, the 15 superexchanges can be divided in 5 groups. Group 1 is made of J(Fe,Fe), J(Cr,Cr), J(Ni,Ni), J(Fe,Ni) and J(Cr,Co) that have similar values from the analysis above and similar to the effective +J. Group 2 contains J(Fe,Cr) and J(Fe,Co) and its magnitude is +J/2. Group 3 contains J(Co,Co) and J(Co,Ni) and its magnitude is −J/2. Group 3 contains J(Co,Co) and J(Co,Ni) with value −J/4 (the smallest in magnitude). Group 4 contains J(Mn,Mn), J(Fe,Mn), J(Co,Mn) and J(Cr,Mn) with value −J/2. Finally, Group 5 only has J(Mn,Ni) with value −J.

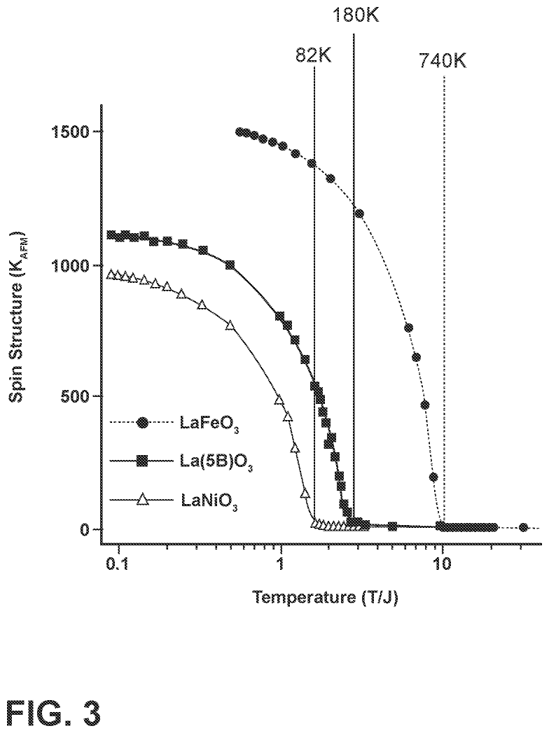

FIG. 3 shows the results of a Monte Carlo simulation for the calculated magnetic responses of the L5BO system in comparison to two related, well-studied ternary (non-complex) systems that are used as reference points as to the transition temperature of the present L5BO system. More particularly, the T/J values were aligned with the known transition temperatures of the two non-complex systems to obtain the scale between T/J and the Neel temperature TN. Despite the many FM couplings used, no peak at the FM (0,0,0) was detected. S(k_{AFM}), with k_{AFM}=(π, π, π), i.e. (½, ½, ½), is shown as a function of temperature for the pure 100% Fe—O—Fe case (with the largest spin), the 100% Ni—O—Ni (with the smallest spin), and the 20% equiatomic B-site populated L5BO. Considering that T_{N}=740 K for pure LaFeO₃, this establishes the scale J in the graph to be ≈82 K after rescaling of existing Monte Carlo results, giving a theoretical prediction that L5BO is AFM with T_{N}≈210 K at step 104 of the method. The AFM found in simulation is percolated rather than isolated, which matches the long-range AFM order observed in experiment. As only a single transition temperature is observed, it is therefore possible at step 106 of the method to grossly design critical temperature and macroscopic ordering type by selecting elemental compositions based on the average of their S and J parameters. This opens continuously tunable magnetic phase spaces that are not accessible using less complex compositions where enthalpy-dominated synthesis results in local clustering and disruption of structural uniformity. However, the percolated AFM state in L5BO should not be confused with a traditional macroscopically phase pure ordering where all nearest neighbors have AFM exchange interactions. In the equiatomic L5BO system, the FM bonds account for ⅖ of the total exchange interactions in the material. Despite the dominance of long-range AFM, regions of ferromagnetically coupled neighbors are clearly observed via simulation and experiment embedded in a continuous antiferromagnetic matrix. These FM regions appear in simulations at the same critical temperature as AFM order but are not coherently coupled, which prevents percolation of the FM state. This intrinsic frustration in the L5BO magnetic lattice is highlighted by the non-collinearity of the equilibrated spins; and while AFM order dominates, a simple average of the parent oxides' magnetic state does not complete the story. The distribution of superexchanges, J(Si·Sj), prior to equilibrium explains how FM character may play a more visible role at higher temperatures.

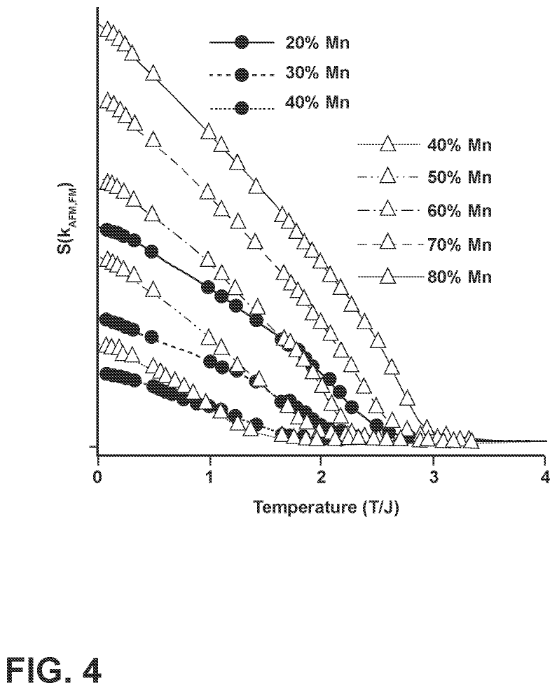

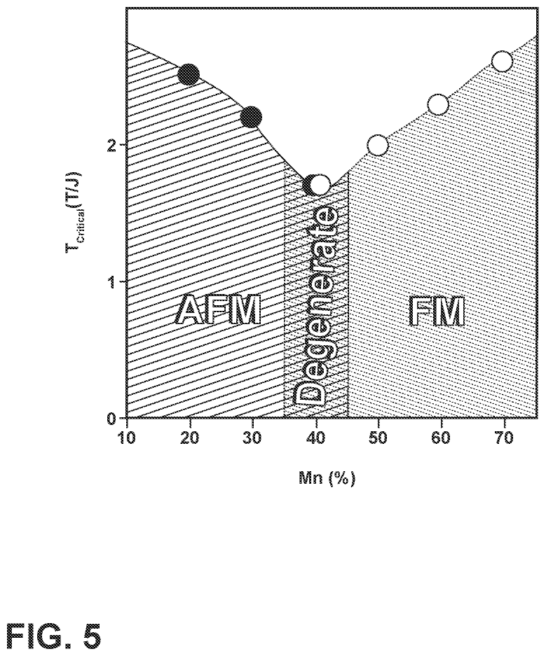

To further test the relationship of AFM and FM in the L5BO system, at step 106 of the method the effects of iteratively shifting the composite state to lower J is modelled by increasing the ratio of Mn concentration in the lattice. Analyzing the set of superexchange values, X—O—Y links containing Mn favor ferromagnetism. Consequently, it is expected that increasing the relative Mn concentration in the Monte Carlo simulations should eventually lead to global ferromagnetism. Comparative Monte Carlo simulations provide expected spin structure factors as the percentage of Mn increases in relation to the other transition metals populating the lattice, where 20% is equiatomic L5BO. In FIG. 4, it is shown that as the percentage of Mn initially increases to 30%, the Néel temperature decreases, but still S(0,0,0) is negligible and indicates no clear FM order. However, at 40%, a FM signal at k_{FM}=(0,0,0) develops and in concert with the AFM signal at k_{AFM}=(π, π, π). This is indicative of a degenerate tipping point between phase preferences, visualized as an incipient quantum critical point in FIG. 5. Both signals grow at the same temperature upon cooling. Snapshots of MC simulations visually suggest that the FM clusters have percolated at the 40% Mn concentration, with both the FM and AFM regions being coherent over long distances. At 50% Mn or larger, the AFM S(k) becomes negligible. Increasing Mn to 50% and beyond leads to the FM and AFM states switching roles, with unpercolated AFM clusters being embedded in the fully percolated FM matrix. From this, we see that the model predicts an ability to select and control the dominant percolated magnetic phase, the T_{N} and T_{C} of the percolated phases, and that it is even possible to balance the J and S composition in such a way that both AFM and FM can be fully expressed and coexisting as seen in the 40% Mn composition.

Single crystal films of La(Cr_{0.15}Mn_{0.4}Fe_{0.15}Co_{0.15}Ni_{0.15})O₃ (40% Mn) and La(Cr_{0.1}Mn_{0.6}Fe_{0.1}Co_{0.1}Ni_{0.1})O₃ (60% Mn) were then synthesized at step 108 of the method to test the model's predictions experimentally. Samples were prepared using pulsed laser epitaxy on 5 mm×5 mm×0.5 mm SrTiO₃ and (La_{0.3}Sr_{0.7})(Al_{0.65}Ta_{0.35})O₃ (LSAT) substrates. In addition to equiatomic (20%) films, the 40% and 60% Mn films were synthesized using the same growth parameters with the only difference being that the PLD ceramic targets were of appropriate stoichiometry. All films were single phase, epitaxial, and possessed thickness uniformity. Film thicknesses were 56 nm for 40% Mn, 58 nm for 60% Mn, and 62 nm for LSBO (20% Mn) films. The film used for neutron diffraction (grown on LSAT) was ˜90 nm.

The 40% Mn and 60% Mn films synthesized after computational modelling described above suggests that these compositions reside at positions in the magnetic phase diagram that possess fully percolated coexisting FM and AFM phases for 40% and single percolated FM phase for 60%. These particular compositions had never been previously reported. Anecdotally, it was found that these films grew very easily using the identical synthesis conditions to those used for the 20% Mn sample. All films are single phase, epitaxial, and possess excellent uniformity.

Magnetization measurements, both as a function of applied field and temperature, were performed using a Quantum Design MPMS3. A linear (with magnetic field) subtraction of the diamagnetic background of the substrate was performed for all loops. Data was normalized by considering the volume of the film (using the thicknesses above) using the perovskite unit cell based on lattice parameters found from XRD.

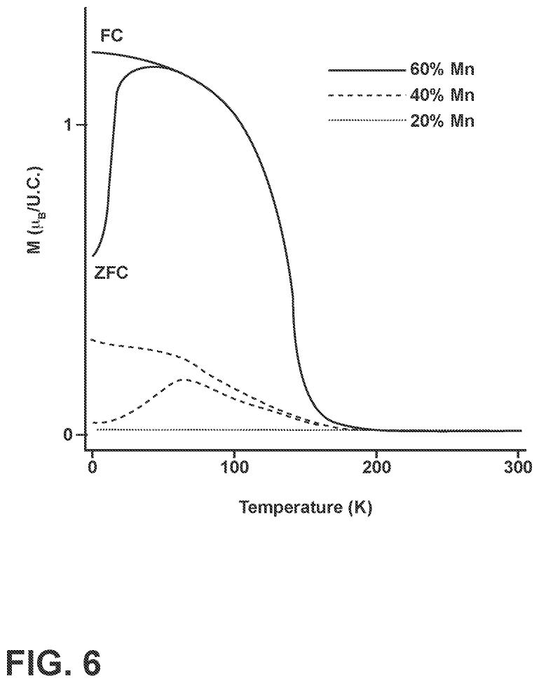

In FIG. 6, temperature-dependent magnetizations of the synthesized films show that increasing Mn concentration significantly changes the magnetic responses in agreement with the model. The 60% Mn concentration presents a single sharp upturn in moment consistent with a ferromagnet with T_{C}≈160 K. The 40% Mn composition has a slightly lower critical temperature than the 20% and 60% compositions and a more gradual transition region as would be expected for competing AFM and FM phases. Precise T_{N} and T_{C} cannot be extracted from magnetometry alone in this mixed system; however, if the local spin and exchange landscape in the synthesized films does mimic the complexity predicted in the model, there should be a high degree of exchange frustration and spin disorder populating these lattices. This would lead to behaviors which may mimic those traditionally observed at the interface of thin film heterostructures comprised of interfacing AFM and FM layers, where intentional design of these exchange interaction discontinuities is used to manipulate exchange bias effects for spin valve, logic, and storage applications. Increasing the disorder and uncompensated spin populations at the interface of these heterostructures may be the dominating influence in all AFM-FM exchange bias devices. From this, the extraordinary level of spin disorder and percolative nature of the AFM and FM phases hosted in the high entropy oxide films could provide the needed environment to generate exchange bias responses in 3D monolithic systems.

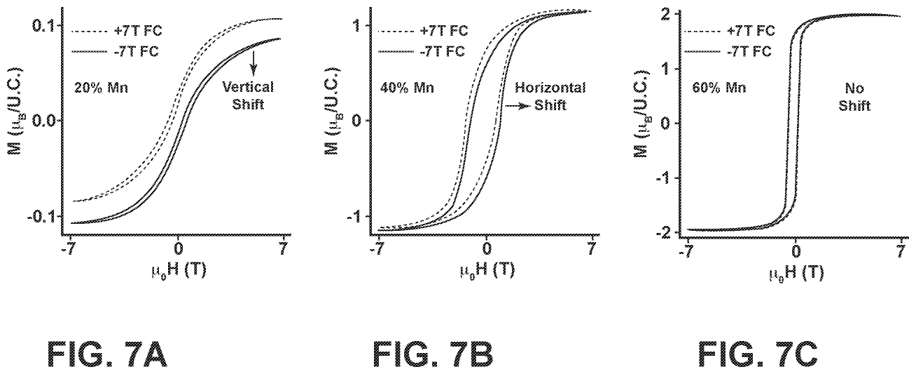

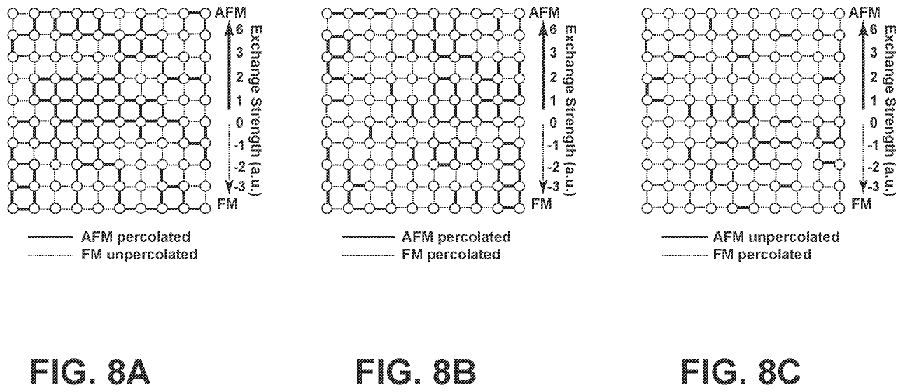

The comparative positive and negative field-cooled magnetization loops shown in FIGS. 7a-c indicate the presence and clear evolution of exchange bias behaviors with Mn concentration, moving from a vertical loop shift at 20% Mn in FIG. 7a, to a horizontal loop shift at 40% Mn in FIG. 7b, to a loss of biasing effects at 60% Mn in FIG. 7c. These functional changes can be understood as arising from a shift in the dominant percolative phases populating the lattice, where FIGS. 8a-c provide corresponding representative 10×10 cross sections from the equilibrated Monte Carlo simulations. In the 20% Mn system, the AFM phase alone is percolated as shown in FIG. 8a. The vertical shift in magnetization results from aligning pockets of uncompensated or isolated FM moments, which creates a surplus magnetization when field cooling the sample below the AFM phase's blocking temperature. In the 40% Mn system, both the AFM and FM phases are percolated as shown in FIG. 8b. The horizontal shift in magnetization is clear evidence of the traditional exchange biasing behavior associated with coexisting and coupled FM and AFM phases of similar energy scale. In the 60% Mn system, the FM phase alone is percolated as shown in FIG. 8c. There is no observable loop shift and the saturation moment aligns well with that expected for this composition of Mn in the S=3/2 state.

Varying the compositional amount of Mn while keeping the balance of the amounts of the other transition metals equal is described above. Varying the amount of Mn is significant because Mn almost always couples with the other transition metals as ferromagnetic. However, it should be understood that the same steps may be taken for other elements such as Fe by varying the amount of Fe while keeping the balance of the amounts of the other transition metals equal. In contrast to Mn, Fe almost always couples with the other transition metals as antiferromagnetic. Of course, each of the other three elements (Cr, Co, Ni) may be varied in the same manner.

Thus, in embodiments of the method 100 of forming a monolithic single crystal film, a magnetic phase diagram such as shown in FIGS. 4 and 5 is created at step 102 by calculating spin structure factor S(k) of the cubic lattice at each of various compositional amounts of one (or more) of the transition metals. At step 104, the critical transition temperature can be obtained from the spin structure factor S(k) as shown in FIGS. 3 and 4 to convert the phase diagram of FIG. 4 into the phase diagram shown in FIG. 5. Next, at step 106 the composition ratio of the transition metals are selected from the phase diagram and associated spin structure factors S(k) based on the desired magnetic behavior. For example, the fractional amount of one of the transition metals may be varied between 0.1 and 0.9, while keeping the balance of the other transitional metals equal, to obtain a material exhibiting one of antiferromagnetism, paragmagnetism, ferromagnetism, or magnetic frustration of co-existing states. Further, the fractional amount of more than one of the transition metals may be separately varied between 0 and 1, alternatively between 0.1 and 0.9, while adjusting the fractional amounts of the other transition metals to maintain the sum total of their fractional amounts equal to 1.0. Then, at step 108, a single crystal film including the transition metals at the selected composition ratios is synthesized.

This control over magnetic coupling in 3D monolithic, single phase, single crystal films is remarkable, as the exchange bias response is traditionally associated with heterostructured or 2D layered magnetic materials, where direct coupling is subject to multiple crystalline components. These observations present an important new direction in understanding the dominating mechanism of exchange bias behaviors more generally. As shown herein, manipulating the local spin disorder can be used to drive exchange bias behaviors in the monolithic single crystal films which resemble responses normally only accessible through intentionally designed heterojunctions. This provides important new insights into recent proposals that spin-disorder driven glassiness can be a dominating factor in generating exchange bias responses.

Traditional enthalpy-driven synthesis approaches often create materials that possess unintended secondary crystal phase formations or defects which generate extrinsic contributions when more than a few elements are combined. This limits the synthesis of desired functional states in a continuously tunable manner and excludes simple models using only intrinsic parameter variables. Experimental access to narrow regions of calculated parameter space is a critical need to enable computational materials design strategies. The presented work demonstrates that the compositionally disordered but positionally ordered lattices produced using entropy-assisted synthesis may greatly simplify our ability to create magnetic materials by design. Beyond the continuously tunable critical temperatures of the dominant magnetic phase in films, the emergence of exchange bias responses in these single crystals is functionally important. This feature is entirely unique from the parent oxides and may lead to the development of spin-based electronics that do not rely on heterostructuring.

Manipulating the strength and type of coexisting and randomly distributed microstates populating a well-ordered single crystal offers opportunities to explore the effects of disorder in the strong limit, which is particularly important in a system where frustration and degeneracy may lead to unexpected or previously inaccessible phase spaces. Mixing elements having similar magnitude of exchange strength but opposite sign may allow intentional design of metastability, dynamic responses, and near global frustration into the lattice. As an example, magnetic frustration has been explored extensively on triangular, pyrochlore, and artificial lattices, where observation of dynamic magnetic behaviors such as spin liquids are generally attributed to degenerate ground states relying on geometric frustration. In magnetically complex high entropy oxides such as those described in this work, it may be possible to replace geometric frustration with exchange frustration on a square lattice by modifying the variance of exchange couplings populating the crystal. The ability to shift local variances in spin and coupling types while maintaining position symmetries also provides exciting opportunities for designing novel Griffiths phases or quantum many-body systems with tunable critical behaviors. From this context, the ability to control the scale of parameter disorder hosted on a lattice may be considered as an exploitable tuning parameter for designing responses in functional materials.

While the single phase compositionally complex material is described above as a monolithic single crystal film of LB5O, it should be understood that the single phase compositionally complex material may be formed with other synthesis methods. Thus, the single phase compositionally complex material alternatively may be a polycrystalline film or a single phase bulk ceramic. For example, instead of being a single crystal film, the material may be in the form of a bulk magnet.

The above description is that of current embodiments of the invention. Various alterations and changes can be made without departing from the spirit and broader aspects of the invention as defined in the appended claims, which are to be interpreted in accordance with the principles of patent law including the doctrine of equivalents. This disclosure is presented for illustrative purposes and should not be interpreted as an exhaustive description of all embodiments of the invention or to limit the scope of the claims to the specific elements illustrated or described in connection with these embodiments. For example, and without limitation, any individual element(s) of the described invention may be replaced by alternative elements that provide substantially similar functionality or otherwise provide adequate operation. This includes, for example, presently known alternative elements, such as those that might be currently known to one skilled in the art, and alternative elements that may be developed in the future, such as those that one skilled in the art might, upon development, recognize as an alternative. Further, the disclosed embodiments include a plurality of features that are described in concert and that might cooperatively provide a collection of benefits. The present invention is not limited to only those embodiments that include all of these features or that provide all of the stated benefits, except to the extent otherwise expressly set forth in the issued claims. Any reference to claim elements in the singular, for example, using the articles “a,” “an,” “the” or “said,” is not to be construed as limiting the element to the singular.

What is claimed is:

1. A method of forming a single phase compositionally complex material including a plurality of transition metals, the method comprising:
creating a magnetic phase diagram to predict magnetic behavior, by calculating expected local magnetic states leading to macroscopic behavior using the formula:
$$H = {\sum }_{< ij >} {J}_{ij} {S}_{i} \cdot {S}_{j}$$
wherein Sᵢ are spin values depending on which transition metal is placed at site i, Sⱼ are spin values depending on which transition metal is placed at site j, <ij> refers to next nearest-neighbor sites, and Jᵢⱼ are magnetic exchange values, and calculating the spin structure factor S(k) by Fourier transform, using the formula:
$$S ( k ) = \frac{1}{N} {\sum }_{i , j} 〈 {S}_{i} \cdot {S}_{j} 〉 {e}^{ik \cdot 〈 {r}_{i} - {r}_{j} 〉}$$
wherein rᵢ is the vector position of site i, rⱼ is the vector position of site j, k is the wavevector that is set to (0,0,0) and (½,½,½), and <Sᵢ·Sⱼ> are the standard spin-spin correlations in real space at all distances;
obtaining a transition temperature from the spin structure factor;
selecting the plurality of transition metals and corresponding transition metal composition ratios for the single phase compositionally complex material based on a desired magnetic behavior and the calculated spin structure factor S(k); and
forming the single phase compositionally complex material, wherein the single phase compositionally complex material is a compositionally complex transition metal oxide comprising the plurality of transition metals at the selected composition ratios.

2. The method of claim 1, wherein the spin values S are: (i) S=5/2 when the transition metal is Fe; (ii) S=2 when the transition metal is Co; (iii) S=3/2 when the transition metal is Mn; (iv) S=3/2 when the transition metal is Cr; and (v) S=1 when the transition metal is Ni.

3. The method of claim 1, wherein the magnetic exchange values J are obtained from the following table:

| Coupling (oxygen-mediated | Exchange |
|---|---|
| occupancy at lattice sites ij) | Value J (mev) |
| Ni—Mn | −8.6 |
| Co—Mn | −4.6 |
| Mn—Cr | −3.9 |
| Fe—Mn | −3.7 |
| Mn—Mn | −3.4 |
| Co—Ni | −1.6 |
| Co—Co | −1.4 |
| Fe—Cr | 4.2 |
| Co—Fe | 4.4 |
| Cr—Co | 5.9 |
| Ni—Cr | 6.0 |
| Fe—Fe | 7.1 |
| Cr—Cr | 7.8 |
| Fe—Ni | 8.3 |
| Ni—Ni | 9.4 |

4. The method of claim 1, wherein the step of creating a magnetic phase diagram includes varying a compositional amount of one of the transition metals and repeating the calculation of the expected local magnetic states and spin structure factor S(k) for each compositional amount.

5. The method of claim 1, wherein the plurality of transition metals includes more than three transition metals.

6. The method of claim 1, wherein the compositionally complex transition metal oxide is La(CrₐMn_{b}Fe_{c}Co_{d}Niₑ)O₃ in which a+b+c+d+e=1 and each of a, b, c, d, and e is greater than 0 and less than 1.

7. The method of claim 6, including the step of varying one or more of a, b, c, d, and e in the range of 0.1 to 0.9.

8. The method of claim 1, wherein the compositionally complex transition metal oxide is La(Cr_{(1-n)/4}MnₙFe_{(1-n)/4}Co_{(1-n)/4}Ni_{(1-n)/4})O₃, 0>n>1 and n is selected based on the desired magnetic behavior and transition temperature.

9. The method of claim 1, wherein the compositionally complex transition metal oxide is La(Cr_{(1-n)/4}Mn_{(1-n)/4}FeₙCo_{(1-n)/4}Ni_{(1-n)/4})O₃, 0>n>1 and n is selected based on the desired magnetic behavior and transition temperature.

10. The method of claim 1, wherein the compositionally complex transition metal oxide is La(CrₙMn_{(1-n)/4}Fe_{(1-n)/4}Co_{(1-n)/4}Ni_{(1-n)/4})O₃, 0>n>1 and n is selected based on the desired magnetic behavior and transition temperature.

11. The method of claim 1, wherein the compositionally complex transition metal oxide is La(Cr_{(1-n)/4}Mn_{(1-n)/4}Fe_{(1-n)/4}CoₙNi_{(1-n)/4})O₃, 0>n>1 and n is selected based on the desired magnetic behavior and transition temperature.

12. The method of claim 1, wherein the compositionally complex transition metal oxide is La(Cr_{(1-n)/4}Mn_{(1-n)/4}Fe_{(1-n)/4}Co_{(1-n)/4}Niₙ)O₃, 0>n>1 and n is selected based on the desired magnetic behavior and transition temperature.

13. The method of claim 1, wherein the desired magnetic behavior is one of antiferromagnetism, paramagnetism, ferromagnetism, and magnetic frustration of co-existing states.

14. A single crystal film formed by the method of claim 1.

15. The single crystal film of claim 14, wherein the single crystal film is a compositionally complex ABO₃ perovskite film.

16. The single crystal film of claim 15, wherein A is La and B is the plurality of transition metals including Cr, Mn, Fe, Co, and Ni.

17. The single crystal film of claim 14, wherein the single crystal film exhibits exchange bias.

18. A compositionally complex transition metal oxide having the formula La(CrₐMn_{b}Fe_{c}Co_{d}Niₑ)O₃ wherein a+b+c+d+e=1 and each of a, b, c, d, and e is greater than 0 and less than 1.

19. The compositionally complex transition metal oxide of claim 18, wherein any one of a, b, c, d, and e is equal to n, and the others of a, b, c, d, and e are each equal to (1−n)/4.

20. The compositionally complex transition metal oxide of claim 19, wherein a=(1−n)/4, b=n, c=(1−n)/4, d=(1−n)/4, e=(1−n)/4, and 0>n>1.
